(19) United States
(12) Patent Application Publication
(10) Pub. No.: US 2025/0392293 A1
(43) Pub. Date: Dec. 25, 2025

(54) LOW-POWER SELF-BIASED SLEW RATE ENHANCEMENT CIRCUIT AND INTEGRATOR

(71) Applicant: NO.24 RESEARCH INSTITUTE OF CHINA ELECTRONICS TECHNOLOGY GROUP CORPORATION, Chongqing (CN)

(72) Inventors: Yan WANG, Chongqing (CN); Zhiyu ZHAO, Chongqing (CN); Yuxin WANG, Chongqing (CN); Hong LIAO, Chongqing (CN); Ruzhang LI, Chongqing (CN); Xiaoyu YANG, Chongqing (CN); Wei XIAO, Chongqing (CN); Yixiao ZHU, Chongqing (CN)

(73) Assignee: NO.24 RESEARCH INSTITUTE OF CHINA ELECTRONICS TECHNOLOGY GROUP CORPORATION, Chongqing (CN)

(21) Appl. No.: 19/286,234

(22) Filed: Jul. 30, 2025

Related U.S. Application Data
(63) Continuation of application No. PCT/CN2025/070311, filed on Jan. 3, 2025.

(30) Foreign Application Priority Data
Jun. 24, 2024 (CN) 202410821446.4

(51) Int. Cl. H03K 5/04; H03K 17/687

(52) U.S. Cl. CPC H03K 5/04; H03K 17/6871

(57) ABSTRACT

A low-power self-biased slew rate enhancement circuit includes a self-bias control circuit outputting a bias voltage based on the output voltage of an input voltage detection circuit; the input voltage detection circuit is connected to the self-bias control circuit to detect the magnitude of a differential input voltage; and a slew rate control circuit is used to provide a source current or a sink current to the output end of an operational amplifier when the voltage at the differential input voltage ends exceeds a turn-on voltage, otherwise, no additional current is generated and no slew rate enhancement effect is generated.

### CROSS REFERENCE TO RELATED APPLICATION

The present disclosure is a continuation application of International Patent Application No. PCT/CN2025/070311, filed on Jan. 3, 2025, which claiming the priority to Chinese Application No. 202410821446.4 filed on Jun. 24, 2024, the contents of all of which are incorporated herein by reference in their entirety for all purposes.

### TECHNICAL FIELD

The present application relates to the field of integrated circuits, and in particular to a low-power self-biased slew rate enhancement circuit and an integrator.

### BACKGROUND

The slew rate and the conversion rate of the operational amplifier output voltage are important parameters to measure the settling speed of the operational amplifier when a large amplitude signal is applied. It is defined as the slope of the linear phase of the operational amplifier output change when a large amplitude step signal is input. It is related to the static operating current and load capacitance, as shown in the following formula:

$$SR = \frac{I}{{C}_{L}} .$$

The operational amplifier is a key circuit unit of the switched capacitor circuit. For example, the switched capacitor circuit in the Sigma-Delta integrator includes an operational amplifier and a switched capacitor circuit, in which the sampling capacitor and the integrating capacitor both contribute to the load capacitance. Therefore, the operational amplifier is required to have a slew rate that is large enough to achieve rapid charge transfer between capacitors.

### SUMMARY

The present application provides a low-power self-biased slew rate enhancement circuit, which includes: differential input voltage ends Vᵢₙ₊ and Vᵢₙ₋, differential output voltage ends Vₒᵤₜ₊ and Vₒᵤₜ₋, a self-bias control circuit, an input voltage detection circuit, and a slew rate control circuit, wherein the differential input voltage ends Vᵢₙ₊ and Vᵢₙ₋ are used to connect to the differential input voltage ends of an operational amplifier, and the differential output voltage ends Vₒᵤₜ₊ and Vₒᵤₜ₋ are used to connect to the differential output voltage ends of the operational amplifier; the self-bias control circuit has an input end connected to an output end of an input voltage detection circuit and outputs a bias voltage based on an output voltage of the input voltage detection circuit; the input voltage detection circuit has input ends connected to an output end and differential input voltage ends of the self-bias control circuit respectively; output ends of the input voltage detection circuit are connected to the input end of the self-bias control circuit and an input end of the slew rate control circuit respectively; the slew rate control circuit is connected to the differential output voltage ends Vₒᵤₜ₊ and Vₒᵤₜ₋, to provide a source current or a sink current to an output end of the operational amplifier when an output voltage of the differential input voltage ends Vᵢₙ₊ and Vᵢₙ₋ exceeds a turn-on voltage so as to enhance a rising edge slew rate or a falling edge slew rate, otherwise, no additional current is generated and no slew rate enhancement effect is generated.

The present application also provides an integrator including the low-power self-biased slew rate enhancement circuit, an operational amplifier, and a switch capacitor; the switch capacitor is differential, and its single end includes a first switch S1 to a fourth switch S4, a sampling capacitor Cs, and an integration capacitor C1; the first switch S1 and the second switch S2 are controlled by a sampling phase timing ϕ1, and the third switch S3 and the fourth switch S4 are controlled by the integrating phase timing ϕ2, one end of the first switch S1 is connected to an input voltage V_{P} of an integrator, and the other end of the first switch S1 is connected to a lower plate of the sampling capacitor Cs, two ends of the second switch S2 are respectively connected to an upper plate of the sampling capacitor Cs and a common mode voltage V_{CM}, two ends of the third switch S3 are respectively connected to a lower plate of the sampling capacitor Cs and the common mode voltage V_{CM}, two ends of the fourth switch S4 are respectively connected to an upper plate of the sampling capacitor Cs and an input end Vᵢₙ₊ of the operational amplifier, and the integration capacitor C1 is connected across the input end Vᵢₙ₊ and the output end Vₒᵤₜ₋ of the operational amplifier; the low-power self-biased slew rate enhancement circuit is differential, and its differential input voltage ends Vᵢₙ₊ and Vᵢₙ₋ are respectively connected to the differential input voltage ends Vᵢₙ₊ and Vᵢₙ₋ of the operational amplifier, and the differential output voltage ends Vᵢₙ₊ and Vᵢₙ₋ are respectively connected to the differential output voltage ends Vₒᵤₜ₋ and Vₒᵤₜ₊ of the operational amplifier.

### BRIEF DESCRIPTION OF DRAWINGS

In order to more clearly illustrate the technical solution of the embodiments of the present application, the drawings required for use in the description of the embodiments of the present application are briefly introduced below.

FIG. 1 is a block diagram of a low-power self-biased slew rate enhancement circuit architecture according to an embodiment of the present application;

FIG. 2 is a schematic diagram of a low-power self-biased slew rate enhancement circuit with an NMOS input pair according to an embodiment of the present application;

FIG. 3 is a schematic diagram of a low-power self-biased slew rate enhancement circuit with a PMOS input pair according to an embodiment of the present application;

FIG. 4 is an example of applying a self-biased slew rate enhancement circuit in a Sigma-Delta switched capacitor integrator according to an embodiment of the present application.

### DESCRIPTION OF EMBODIMENTS

Existing slew rate enhancement technology is achieved by increasing the static operating current of the operational amplifier, which will increase power consumption. At the same time, since this current acts on the entire amplifier device, there are certain requirements for the length and width selection of the device, which not only increases the chip area but also limits the realization of other important indicators.

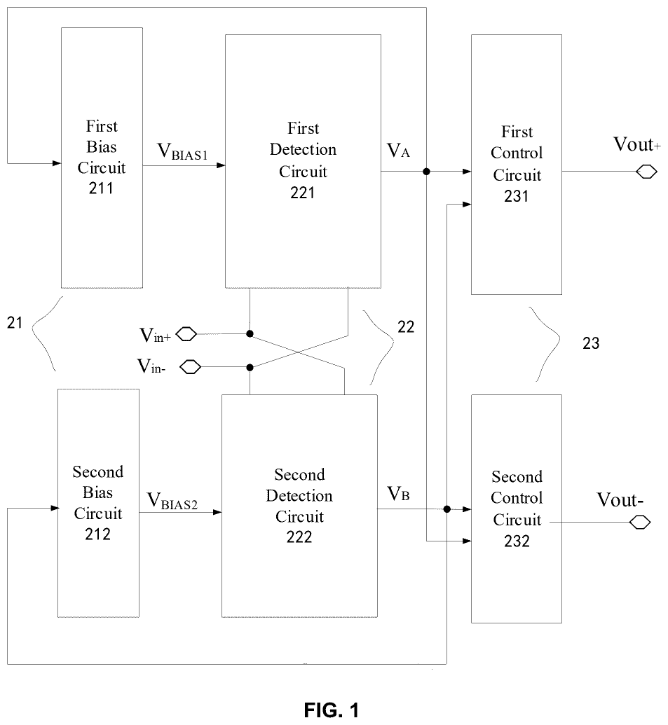

FIG. 1 is a schematic diagram of the architecture of a low-power self-biased slew rate enhancement circuit according to an embodiment of the present application. The low-power self-biased slew rate enhancement circuit can be used in an integrator, and the integrator includes an operational amplifier. The low-power self-biased slew rate enhancement circuit includes differential input voltage ends Vᵢₙ₊ and Vᵢₙ₋, differential output voltage ends Vₒᵤₜ₊ and Vₒᵤₜ₋, a self-bias control circuit 21, an input voltage detection circuit 22, and a slew rate control circuit 23; the differential input voltage ends Vᵢₙ₊ and Vᵢₙ₋ are used to connect to differential input voltage ends of the operational amplifier, and the differential output voltage ends Vₒᵤₜ₊ and Vₒᵤₜ₋ are used to connect to differential output voltage ends of the operational amplifier;

The self-bias control circuit 21 includes a first bias circuit 211 and a second bias circuit 212. The self-bias control circuit is used to provide the current of the low-power self-bias slew rate enhancement circuit and perform control according to the output of the voltage detection circuit. When the differential input voltage ends Vᵢₙ₊ and Vᵢₙ₋ do not exceed the turn-on voltage, the low-power self-bias slew rate enhancement circuit has no current consumption, otherwise, there is current consumption.

The input voltage detection circuit 22 includes a first detection circuit 221 and a second detection circuit 222. The input voltage detection circuit is connected to the differential input voltage ends Vᵢₙ₊ and Vᵢₙ₋ to detect whether the difference between Vᵢₙ₊ and Vᵢₙ₋ exceeds the turn-on voltage. The output voltage is connected to the self-bias circuit and the slew rate control circuit.

The slew rate control circuit 23 includes a first control circuit 231 and a second control circuit 232; the slew rate control circuit is connected to the differential output voltage ends Vₒᵤₜ₊ and Vₒᵤₜ₋, and when the differential input voltage ends Vᵢₙ₊ and Vᵢₙ₋ exceed the turn-on voltage, an additional source current or sink current is provided to the output end of the main operational amplifier to enhance the rising edge slew rate or the falling edge slew rate, otherwise no additional current is generated and no slew rate enhancement effect is generated.

The first input end and the second input end of the first detection circuit 221 are respectively used to connect the differential input signals Vᵢₙ₊ and Vᵢₙ₋ of the operational amplifier, and the third input end is connected to the output V_{BIAS1} of the first bias circuit 211, and the output of the first detection circuit is V_{A}, which serves as the input of the first bias circuit 211 and is connected to the first input end of the first control circuit 231 and the second input end of the second control circuit 232.

The first input end and the second input end of the second detection circuit 222 are respectively used to connect the differential input signals Vᵢₙ₋ and Vᵢₙ₊ of the operational amplifier, the third input end is connected to the output V_{BIAS2} of the second bias circuit 212, and the output of the second detection circuit is V_{B}, which serves as the input of the second bias circuit 212 and is connected to the second input end of the first control circuit 231 and the first input end of the second control circuit 232. The outputs of the first control circuit 231 and the second control circuit 232 are connected to the differential output signals Vₒᵤₜ₊ and Vₒᵤₜ₋ of the operational amplifier.

When the input differential signal |Vᵢₙ₊−Vᵢₙ₋|<VP, the output V_{A} of the first detection circuit 221 causes the first bias circuit 211 to generate no current, and the generated bias voltage V_{BIAS1} causes the first detection circuit 221 to have no current, the output V_{B} of the second detection circuit 222 causes the second bias circuit 212 to generate no current, and the generated bias voltage V_{BIAS2} causes the second detection circuit 222 to have no current, V_{A} and V_{B} control the first control circuit 231 and the second control circuit 232 so that they do not generate current and cannot directly provide additional current of the output voltage ends Vₒᵤₜ₊ and Vₒᵤₜ₋ to the output node of the operational amplifier, and the self-biased slew rate enhancement amplifier circuit does not work and consumes no current.

When the input differential signal Vᵢₙ₊−Vᵢₙ₋>V_{P}, the first detection circuit 221 works together with the first bias circuit 211 to make V_{A} high level/low level, and the second detection circuit 222 works together with the second bias circuit 212 to make V_{B} low level/high level. V_{A} and V_{B} serve as the first and second input ends of the first control circuit 231, and the second and first input ends of the second control circuit 232, respectively, directly providing the output node of the operational amplifier with additional sink current to the output voltage end Vₒᵤₜ₊ and source current to Vₒᵤₜ₋, thereby improving the rising edge slew rate of Vₒᵤₜ₊ and the falling edge slew rate of Vₒᵤₜ₋, thereby improving the rising edge slew rate of the differential output voltage.

When the input differential signal Vᵢₙ₋−Vᵢₙ₊>V_{P}, the first detection circuit 221 works together with the first bias circuit 211 to make V_{A} a low level/high level, and the second detection circuit 222 works together with the second bias circuit 212 to make V_{B} a high level/low level. V_{A} and V_{B} serve as the first input end and the second input end of the first control circuit 231, and as the second input end and the first input end of the second control circuit 232, respectively, directly providing the output node of the operational amplifier with additional source current of the output voltage end Vₒᵤₜ₊ and sink current of Vₒᵤₜ₋, thereby improving the falling edge slew rate of Vₒᵤₜ₊ and the falling edge slew rate of Vₒᵤₜ₋, thereby improving the falling edge slew rate of the differential output voltage.

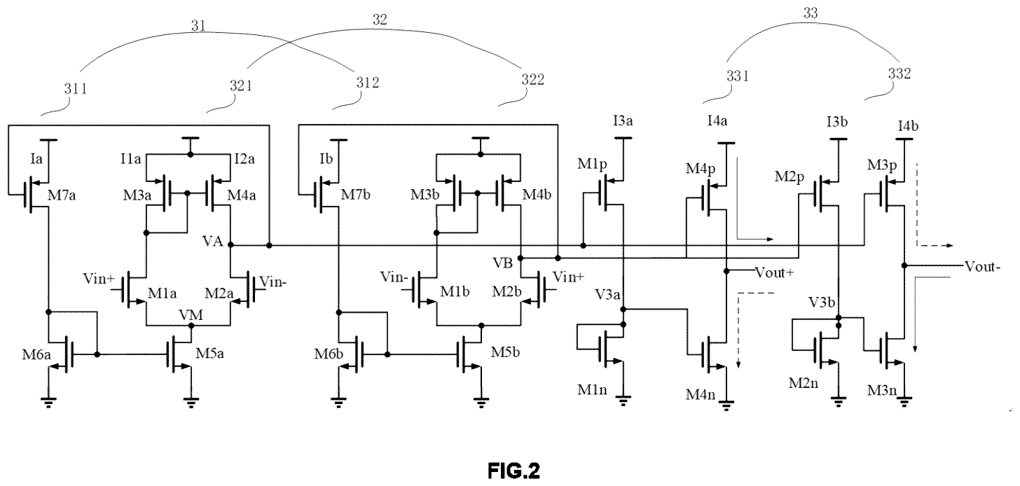

FIG. 2 is a low-power self-biased slew rate enhancement amplifier circuit with an NMOS input pair according to an embodiment of the present application, including a self-bias control circuit 31, an input voltage detection circuit 32, and a slew rate control circuit 33.

The self-bias control circuit 31 includes a first bias circuit 311 and a second bias circuit 312 with the same structure and parameters. The input voltage detection circuit 32 includes a first detection circuit 321 and a second detection circuit 322 with the same structure and parameters and an input pair of NMOS. The slew rate control circuit 33 includes a first control circuit 331 and a second control circuit 332 with the same structure and parameters. The first detection circuit 321 is connected to the first bias circuit 311, the first control circuit 331, and the second control circuit 332; and the second detection circuit 322 is connected to the second bias circuit 312, the second control circuit 332, and the first control circuit 331. The first input end and the second input end of the first detection circuit 321 are respectively used to connect to the differential input voltage ends Vᵢₙ₊ and Vᵢₙ₋ of the operational amplifier, and the first input end and the second input end of the second detection circuit 322 are respectively used to connect to the differential input voltage ends Vᵢₙ₊ and Vᵢₙ₋ of the operational amplifier. The output ends of the first detection circuit 331 and the second detection circuit 332 are respectively connected to the differential output voltage ends Vₒᵤₜ₊ and Vₒᵤₜ₋ of the operational amplifier.

In an embodiment, the first bias circuit includes a first PMOS transistor M7a and a first NMOS transistor M6a, the gate of the first PMOS transistor M7a is connected to the output end of the first detection circuit, the source of the first PMOS transistor M7a is connected to a power supply voltage, the drain of the first PMOS transistor M7a is connected to the drain of the first NMOS transistor M6a, the source of the first NMOS transistor M6a is grounded, the first NMOS transistor M6a adopts a diode-connected form, and the gate of the first NMOS transistor M6a is connected to the first detection circuit to provide a bias circuit for the first detection circuit; the second bias circuit includes a second PMOS transistor M7b and a second NMOS transistor M6b, the gate of the second PMOS transistor M7b is connected to the output end of the second detection circuit, the source of the second PMOS transistor M7b is connected to a power supply voltage, the drain of the second PMOS transistor M7b is connected to the drain of the second NMOS transistor M6b, the source of the second NMOS transistor M6b is grounded, the second NMOS transistor M6b adopts a diode-connected form, and the gate of the second NMOS transistor M6b is connected to the second detection circuit to provide a bias current for the second detection circuit.

In an embodiment, the first detection circuit includes a third NMOS transistor M5a, a fourth NMOS transistor M1a, a fifth NMOS transistor M2a, a third PMOS transistor M3a, and a fourth PMOS transistor M4a; the gate of the third NMOS transistor M5a is connected to the gate of the first NMOS transistor M6a, the source of the third NMOS transistor M5a is grounded, the drain of the third NMOS transistor M5a is respectively connected to the source of the fourth NMOS transistor M1a and the source of the fifth NMOS transistor M2a, the gate of the fourth NMOS transistor M1a and the gate of the fifth NMOS transistor M2a are respectively connected to the differential input voltage ends Vᵢₙ₊ and Vᵢₙ₋, the drain of the fourth NMOS transistor M1a is connected to the drain of the third PMOS transistor M3a, the third PMOS transistor M3a adopts a diode-connected form, the source of the third PMOS transistor M3a is connected to the power supply voltage, the drain of the fifth NMOS transistor M2a is connected to the drain of the fourth PMOS transistor M4a to form the output end of the first detection circuit, the gate of the fourth PMOS transistor M4a is connected to the gate of the third NMOS transistor M5a, and the source of the fourth PMOS transistor M4a is connected to the power supply voltage. The second detection circuit includes a sixth NMOS transistor M5b, a seventh NMOS transistor M1b, an eighth NMOS transistor M2b, a fifth PMOS transistor M3b, and a sixth PMOS transistor M4b; the gate of the sixth NMOS transistor M5b is connected to the gate of the second NMOS transistor, the source of the sixth NMOS transistor M5b is grounded, the drain of the sixth NMOS transistor M5b is respectively connected to the source of the seventh NMOS transistor M1b and the source of the eighth NMOS transistor M2b, the gate of the seventh NMOS transistor M1b and the gate of the eighth NMOS transistor M2b are respectively connected to the differential input voltage ends Vᵢₙ₊ and Vᵢₙ₋, the drain of the seventh NMOS transistor M1b is connected to the drain of the fifth PMOS transistor M3b, the fifth PMOS transistor M3b adopts a diode-connected form, the source of the fifth PMOS transistor M3b is connected to the power supply voltage, the drain of the eighth NMOS transistor M2b is connected to the drain of the sixth PMOS transistor M4b to form the second output end of the second detection circuit, the gate of the fifth PMOS transistor M3b is connected to the gate of the sixth PMOS transistor M4b, and the source of the sixth PMOS transistor M4b is connected to the power supply voltage.

It should be noted that, in the first detection circuit, the fourth NMOS transistor M1a and the fifth NMOS transistor M2a constitute an input NMOS transistor, the third NMOS transistor M5a is a tail current transistor, and the third PMOS transistor M3a and the fourth PMOS transistor M4a are load transistors. The ratio of the width-to-length ratio of the fourth NMOS transistor M1a to the width-to-length ratio of the fifth NMOS transistor M2a is m:1, where m is greater than 1. The third NMOS transistor M5a and the first NMOS transistor M6a form a current mirror to obtain current to provide to the first detection circuit 321 for operation. The ratio of the width-to-length ratio of the third PMOS transistor M3a to the width-to-length ratio of the fourth PMOS transistor M4a is 1:1.

It should be noted that, in the second detection circuit, the seventh NMOS transistor M1b and the eighth NMOS transistor M2b constitute an input transistor, the sixth NMOS transistor M5b is a tail current transistor, and the fifth PMOS transistor M3b and the sixth PMOS transistor M4b are load transistors. The ratio of the width-to-length ratio of the seventh NMOS transistor M1b to the width-to-length ratio of the eighth NMOS transistor M2b is m:1, and the gate of the sixth NMOS transistor M5b is connected to the drain end of the second NMOS transistor M6b in the second bias circuit 312, and forms a current mirror with the second NMOS transistor M6b to obtain current to provide to the second detection circuit 322 for operation. The ratio of the width-to-length ratio of the fifth PMOS transistor M3b to the width-to-length ratio of the sixth PMOS transistor M4b is 1:1.

The first control circuit includes a ninth NMOS transistor M1n, a tenth NMOS transistor M4n, a seventh PMOS transistor M1p and an eighth PMOS transistor M4p, the source of the seventh PMOS transistor M1p is connected to the power supply voltage, the gate of the seventh PMOS transistor M1p is connected to the output end of the first detection circuit, the drain of the seventh PMOS transistor M1p is connected to the drain of the ninth NMOS transistor M1n, the source of the ninth NMOS transistor M1n is grounded, the ninth NMOS transistor M1n adopts a diode-connected form, the source of the eighth PMOS transistor M4p is connected to the power supply voltage, the gate of the eighth PMOS transistor M4p is connected to the output end of the second detection circuit, the drain of the eighth PMOS transistor M4p is connected to the drain of the tenth NMOS transistor M4n and then connected to the differential output voltage end Vₒᵤₜ₊, the source of the tenth NMOS transistor M4n is grounded, and the gate of the tenth NMOS transistor M4n is connected to the drain of the ninth NMOS transistor M1n. The second control circuit includes an eleventh NMOS transistor M2n, a twelfth NMOS transistor M3n, a ninth PMOS transistor M2p and a tenth PMOS transistor M3p, the source of the ninth PMOS transistor M2p is connected to the power supply voltage, the gate of the ninth PMOS transistor M2p is connected to the output end of the second detection circuit, the drain of the ninth NMOS transistor M1n is connected to the drain of the eleventh NMOS transistor M2n, the source of the eleventh NMOS transistor M2n is grounded, the eleventh NMOS transistor M2n adopts a diode connection form, the source of the tenth PMOS transistor M3p is connected to the power supply voltage, the gate of the tenth PMOS transistor M3p is connected to the output end of the first detection circuit, and the drain of the tenth PMOS transistor M3p is connected to the drain of the twelfth NMOS transistor M3n and then connected to the differential output voltage end Vₒᵤₜ₋, the source of the twelfth NMOS transistor M3n is grounded, and the gate of the twelfth NMOS transistor M3n is connected to the drain of the eleventh NMOS transistor M2n.

It should be noted that in the input voltage detection circuit 32, the width-to-length ratio of the input transistors formed by the fourth NMOS transistor M1a, the fifth NMOS transistor M2a, the seventh NMOS transistor M1b, and the eighth NMOS transistor M2b is m:1, which determines the turn-on voltage V_{P} of the embodiment of the present application. Taking the first detection circuit 321 as an example, when the two branch currents I1a and I1b flowing through the detection circuit are equal, according to the saturation region current formula, the gate-source voltages V_{Gs1a} and V_{Gs2a} of the fourth NMOS transistor M1a and the fifth NMOS transistor M2a are respectively:

and it can be determined that

$${V}_{GS 1 a} = {V}_{TH} + \sqrt{\frac{\frac{1}{2} I}{μ {C}_{ox} m ( \frac{W}{L} )}} , and$$

$${V}_{GS 1 a} = {V}_{TH} + \sqrt{\frac{\frac{1}{2} I}{μ {C}_{ox} ( \frac{W}{L} )}} ,$$

$$Vp = {V}_{GS 1 a} - {V}_{GS 2 a} = \sqrt{\frac{\frac{1}{2} I}{μ {C}_{ox} ( \frac{W}{L} )}} ( 1 - \sqrt{\frac{1}{m}} ) .$$

When the input differential signal |Vᵢₙ₊−Vᵢₙ₋|<V_{P}, since the width-to-length ratio of the fourth NMOS transistor M1a in the first detection circuit 321 is greater than that of the fifth NMOS transistor M2a, the current flowing through the fourth NMOS transistor Ma is greater than that flowing through the fifth NMOS transistor M2a. Since the third PMOS transistor M3a and the fourth PMOS transistor M4a form a 1:1 current mirror, the current flowing through the fourth PMOS transistor M4a is greater than that flowing through the fifth NMOS transistor M2a, so that V_{A} becomes a high level. V_{A} controls the first PMOS transistor M7a in the first bias circuit 311, so that the first PMOS transistor M7a is turned off, and no current flows through the first NMOS transistor M6a. The first NMOS transistor M6a and the third NMOS transistor M5a form a current mirror, so no current flows through the third NMOS transistor M5a, so that the first detection circuit 321 has no current and does not work. V_{A} simultaneously controls the seventh PMOS transistor M1p and the tenth PMOS transistor M3p in the slew rate control circuit 33 to turn them off, so the node V3a is at a low level, which serves as the gate voltage of the tenth NMOS transistor M4n, so that the tenth NMOS transistor M4n is also turned off. Similarly, the output voltage V_{B} of the second detection circuit 322 is also at a high level, which will turn off the second bias circuit 312 and the second control circuit 332. Therefore, when the input differential signal |Vᵢₙ₊−Vᵢₙ₋|<V_{P}, the low-power self-biased slew rate enhancement amplifier circuit with the NMOS input pair does not work and does not consume current.

When the input differential signal Vᵢₙ₊−Vᵢₙ₋>V_{P}, the output V_{B} of the second detection circuit 322 is at a low level, so that the second PMOS transistor M7b in the second bias circuit 312 is turned on, generating a current, which is mirrored to the sixth NMOS transistor M5b, providing current to the second detection circuit 322, and maintaining V_{B} at a low level. At the same time, the output V_{A} of the first detection circuit 321 is at a high level, turning off the first bias circuit 311. In the first control circuit 331, the gate end of the seventh PMOS transistor M1p is connected to V_{A} at a high level, so the node V3a is at a low level, the tenth PMOS transistor M4n is turned off, and the gate end of the eighth NMOS transistor M4p is connected to V_{B}, and the eighth NMOS transistor M4p is turned on, so that a sink current is formed to be injected into the output voltage end Vₒᵤₜ₊ of the operational amplifier. In the second control circuit 332, the gate end of the ninth PMOS transistor M2p is connected to V_{B} at a low level, the ninth PMOS transistor M2p is turned on, so that the node V3b is a high level, the twelfth NMOS transistor M3n is turned on, and the gate end of the tenth PMOS transistor M3p is turned off due to being connected to V_{A}, thereby forming a source current to the output voltage end Vₒᵤₜ₋ of the operational amplifier. Therefore, when the input differential signal Vᵢₙ₊−Vᵢₙ₋ >V_{P}, the low-power self-biased slew rate enhancement circuit of the present application works, directly providing the output node of the operational amplifier with an additional sink current of the output voltage end Vₒᵤₜ₊ and a source current of Vₒᵤₜ₋, thereby improving the rising edge slew rate of Vₒᵤₜ₊ and the falling edge slew rate of Vₒᵤₜ₋, thereby improving the rising edge slew rate of the differential output voltage.

When the input differential signal Vᵢₙ₋−Vᵢₙ₊>V_{P}, the principle is similar to the above, the output V_{A} of the first detection circuit 321 is at a low level, the output V_{B} of the second detection circuit 322 is at a high level, the first bias circuit 311 provides current, the second bias circuit 312 is turned off, the first control circuit 331 forms a source current to the output voltage end Vₒᵤₜ₊, and the second control circuit 332 forms a sink current to the output voltage end Vₒᵤₜ₋. Therefore, when the input differential signal Vᵢₙ₋−Vᵢₙ₊>V_{P}, the low-power self-biased slew rate enhancement circuit of the present application works, directly providing the output node of the operational amplifier with additional source current of the output voltage end Vₒᵤₜ₊ and sink current of Vₒᵤₜ₋, improving the falling edge slew rate of Vₒᵤₜ₊ and the rising edge slew rate of Vₒᵤₜ₋, thereby improving the falling edge slew rate of the differential output voltage.

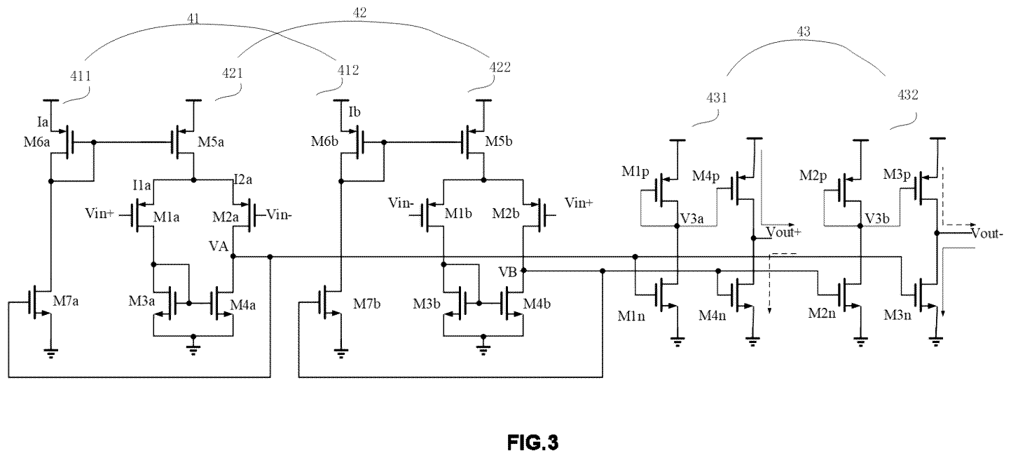

FIG. 3 is a low-power self-biased slew rate enhancement amplifier circuit with a PMOS input pair according to an embodiment of the present application, it includes a self-bias control circuit 41, an input voltage detection circuit 42, and a slew rate control circuit 43. The self-bias control circuit 41 comprises a first bias circuit 411 and a second bias circuit 412 with the same architecture and parameters, the input voltage detection circuit 42 includes a first detection circuit 421 and a second detection circuit 422 with the same architecture and parameters of the input pair being PMOS, and the slew rate control circuit 43 includes a first control circuit 431 and a second control circuit 432 with the same architecture and parameters. The first detection circuit 421 is connected to the first bias circuit 411, the first control circuit 431, and the second control circuit 432, and the second detection circuit 422 is connected to the second bias circuit 412, the second control circuit 432, and the second control circuit 431. The first input end and the second input end of the first detection circuit 421 are respectively connected to the differential input voltage ends Vᵢₙ₊ and Vᵢₙ₋ of the operational amplifier, and the first input end and the second input end of the second detection circuit 422 are Vᵢₙ₋ and Vᵢₙ₊, respectively. The output ends of the first detection circuit 431 and the second detection circuit 432 are connected to the differential output voltage ends Vₒᵤₜ₊ and Vₒᵤₜ₋ of the operational amplifier, respectively.

In an embodiment, the first bias circuit includes: a first PMOS transistor M6a and a first NMOS transistor M7a, the first PMOS transistor M6a adopts a diode-connected form, the source of the first PMOS transistor M6a is connected to the power supply voltage, the drain of the first PMOS transistor is connected to the drain of the first NMOS transistor M7a, the source of the first NMOS transistor M7a is grounded, the gate of the first NMOS transistor M7a is connected to the output end of the first detection circuit, the gate of the first PMOS transistor M6a is connected to the first detection circuit, and the bias current is provided for the first detection circuit. The second bias circuit includes: a second PMOS transistor M6b and a second NMOS transistor M7b, the second PMOS transistor M6b adopts a diode-connected form, the source of the second PMOS transistor M6b is connected to the power supply voltage, the drain of the second PMOS transistor is connected to the drain of the second NMOS transistor M7b, the source of the second NMOS transistor M7b is grounded, the gate of the second NMOS transistor M7b is connected to the output end of the first detection circuit, the gate of the second PMOS transistor is connected to the first detection circuit, and the bias current is provided for the first detection circuit.

In an embodiment, the first detection circuit includes: a third NMOS transistor M3a, a fourth NMOS transistor M4a, a third PMOS transistor M5a, a fourth PMOS transistor M1a, and a fifth PMOS transistor M2a; the source of the third PMOS transistor M5a is connected to the power supply voltage, the gate of the third PMOS transistor M5a is connected to the gate of the first PMOS transistor M6a, the drain of the third PMOS transistor M5a is respectively connected to the source of the fourth PMOS transistor M1a and the source of the fifth PMOS transistor M2a, the gate of the fourth PMOS transistor M1a and the gate of the fifth PMOS transistor M2a are connected to the differential input voltage ends Vᵢₙ₊ and Vᵢₙ₋ respectively, the drain of the fourth PMOS transistor M1a is connected to the drain of the third NMOS transistor M3a, the source of the third NMOS transistor M3a is grounded, the third NMOS transistor M3a adopts a diode-connected form, the drain of the fifth PMOS transistor M2a is connected to the drain of the fourth NMOS transistor M4a, the gate of the fourth NMOS transistor M4a is connected to the gate of the third NMOS transistor M3a, the source of the fourth NMOS transistor M4a is grounded. The second detection circuit includes: a fifth NMOS transistor M3b, a sixth NMOS transistor M4b, a sixth PMOS transistor M5b, a seventh PMOS transistor M1b, and an eighth PMOS transistor M2b; the source of the sixth PMOS transistor M5b is connected to the power supply voltage, the gate of the sixth PMOS transistor M5b is connected to the gate of the second PMOS transistor M6b, the drain of the sixth PMOS transistor M5b is respectively connected to the source of the seventh PMOS transistor M1b and the source of the eighth PMOS transistor M2b, and the gate of the seventh PMOS transistor M1b and the gate and the gate of the eighth PMOS transistor M2b are connected to the differential input voltage ends Vᵢₙ₊ and Vᵢₙ₋ respectively, the drain of the seventh PMOS transistor M1b is connected to the drain of the fifth NMOS transistor M3b, the source of the fifth NMOS transistor M3b is grounded, the fifth NMOS transistor M3b adopts a diode-connected form, the drain of the eighth PMOS transistor M2b is connected to the drain of the sixth NMOS transistor M4b, the gate of the sixth NMOS transistor M4b is connected to the gate of the fifth NMOS transistor M3b, and the source of the sixth NMOS transistor M4b is grounded.

In an embodiment, the first control circuit includes a ninth PMOS transistor M1p, a tenth PMOS transistor M4p, a seventh NMOS transistor M1n, and an eighth NMOS transistor M4n. The ninth PMOS transistor M1p adopts a diode-connected form. The source of the ninth PMOS transistor M1p is connected to the power supply voltage, the drain of the ninth PMOS transistor M1p is connected to the drain of the seventh NMOS transistor M1n, the source of the seventh NMOS transistor M1n is grounded, the gate of the seventh NMOS transistor M1n is connected to the output end of the first detection circuit, the source of the tenth PMOS transistor M4p is connected to the power supply voltage, the gate of the tenth PMOS transistor M4p is connected to the drain of the ninth PMOS transistor M1p, the drain of the tenth PMOS transistor M4p is connected to the drain of the eighth NMOS transistor M4n and connected to the differential output voltage end Vₒᵤₜ₊, the gate of the eighth NMOS transistor M4n is connected to the output end of the second detection circuit, and the source of the eighth NMOS transistor M4n is grounded; the first control circuit includes an eleventh PMOS transistor M2p, a twelfth PMOS transistor M3p, a ninth NMOS transistor M2n, and a tenth NMOS transistor M3n, the eleventh PMOS transistor M2p adopts a diode-connected form, the source of the eleventh PMOS transistor M2p is connected to the power supply voltage, the drain of the eleventh PMOS transistor M2p is connected to the drain of the seventh NMOS transistor M2n, the source of the ninth NMOS transistor M2n is grounded, the gate of the ninth NMOS transistor M2n is connected to the second output end of the first detection circuit, the source of the twelfth PMOS transistor M3p is connected to the power supply voltage, the gate of the twelfth PMOS transistor M3p is connected to the drain of the eleventh PMOS transistor M2p, the drain of the twelfth PMOS transistor M3p is connected to the drain of the tenth NMOS transistor M3n and connected to the differential output voltage end Vₒᵤₜ₋, the gate of the tenth NMOS transistor M3n is connected to the first output end of the second detection circuit, and the source of the tenth NMOS transistor M3n is grounded.

In the first detection circuit, the ratio of the width-to-length ratio of the third NMOS transistor M3a to the width-to-length ratio of the fourth NMOS transistor M4a is 1:1; in the second detection circuit, the ratio of the width-to-length ratio of the seventh PMOS transistor M1b to the width-to-length ratio of the eighth PMOS transistor M2b is m:1, and the sixth PMOS transistor M5b and the second PMOS transistor M6b form a current mirror to obtain a current to provide to the second detection circuit 422. The ratio of the width-to-length ratio of the fifth NMOS transistor M3b to the width-to-length ratio of the sixth NMOS transistor M4b is 1:1.

The first control circuit 431 includes a seventh NMOS transistor M1n and an eighth NMOS transistor M4n, which are connected to the output ends V_{A} and V_{B} of the first detection circuit 421 and the second detection circuit 422 respectively, and a ninth PMOS transistor M1p, a tenth PMOS transistor M4p, and an eleventh PMOS transistor M2p are connected in a form of diode, serving as the load of the seventh NMOS transistor M1n, outputting a voltage V3a, and connected to the gate of the tenth PMOS transistor M4p. The tenth PMOS transistor M4p is a load transistor of the eighth NMOS transistor M4n, and the drain of the eighth NMOS transistor M4n is connected to the drain of the tenth PMOS transistor M4p to form an output voltage end Vₒᵤₜ₊. The second control circuit 432 has the same structure as the first control circuit 431, and includes a ninth NMOS transistor M2n, and a tenth NMOS transistor M3n, which are connected to the output ends V_{B} and V_{A} of the second detection circuit 422 and the first detection circuit 421 respectively, and the output voltage end is Vₒᵤₜ₋.

Similarly, the turn-on voltage

$$Vp = {V}_{GS 1 a} - {V}_{GS 2 a} = \sqrt{\frac{\frac{1}{2} I}{μ {C}_{ox} ( \frac{W}{L} )}} ( 1 - \sqrt{\frac{1}{m}} ) .$$

When the input differential signal |Vᵢₙ₊−Vᵢₙ₋|<V_{P}, since the width-to-length ratio of the fourth PMOS transistor M1a in the first detection voltage 421 is greater than that of the fifth PMOS transistor M2a, the current flowing through the fourth PMOS transistor M1a is greater than that flowing through the fifth PMOS transistor M2a. Since the third NMOS transistor M3a of the load transistor and the fourth NMOS transistor M4a form a 1:1 current mirror, the current flowing through the fourth NMOS transistor M4a is greater than that flowing through the fifth PMOS transistor M2a, so that V_{A} becomes a low level. V_{A} controls the first NMOS transistor M7a in the first bias circuit 411, so that the first NMOS transistor M7a is turned off, and no current flows through the first PMOS transistor M6a. The first PMOS transistor M6a and the third PMOS transistor M5a form a current mirror, so no current flows through the third PMOS transistor M5a, so that the first detection circuit 421 has no current and does not work. Similarly, the output voltage V_{B} of the second detection circuit 422 is also at a low level, which will turn off the second bias circuit 412. V_{A} and V_{B} respectively control the NMOS transistors M1n and M3n in the slew rate control circuit 43, as well as the ninth NMOS transistor M2n and the eighth NMOS transistor M4n, so that they are all turned off. Therefore, nodes V3a and V3b are at a high level, which serves as the gate voltage of the tenth PMOS transistor M4p and the twelfth PMOS transistor M3p, so that the tenth PMOS transistor M4p and the twelfth PMOS transistor M3p are also turned off. Therefore, when the input differential signal |Vᵢₙ₊−Vᵢₙ₋|<V_{P}, the low-power self-biased slew rate enhancement amplifier circuit with the PMOS input pair does not work and does not consume current.

When the input differential signal Vᵢₙ₊−Vᵢₙ₋ >V_{P}, the output V_{A} of the first detection circuit 421 is at a high level, so that the first NMOS transistor M7a in the first bias circuit 411 is turned on, generating current, mirroring to the third PMOS transistor M5a, providing current to the first detection circuit 421, maintaining V_{A} at a high level, and at the same time, the output V_{B} of the second detection circuit 422 is at a low level, turning off the second bias circuit 412. In the first control circuit 431, the gate end of the seventh NMOS transistor M1n is connected to V_{A} at a high level, so the node V3a is at a low level, the tenth PMOS transistor M4p is turned on, and the gate end of the eighth NMOS transistor M4n is turned off due to being connected to V_{B}, thereby forming a sink current to the output voltage end Vₒᵤₜ₊ of the operational amplifier. In the second control circuit 432, the gate end of the ninth NMOS transistor M2n is connected to V_{B} at a low level, the ninth NMOS transistor M2n is turned off, so that the node V3b is at a high level, the twelfth PMOS transistor M3p is turned off, and the gate end of the tenth NMOS transistor M3n is turned on due to being connected to V_{A}, thereby forming a source current to the output voltage end Vₒᵤₜ₋ of the operational amplifier. Therefore, when the input differential signal Vᵢₙ₊−Vᵢₙ₋ >V_{P}, the low-power self-biased slew rate enhancement circuit of the present application works, directly providing the output node of the operational amplifier with an additional sink current to the output voltage end Vₒᵤₜ₊ and a source current to Vₒᵤₜ₋, thereby improving the rising edge slew rate of Vₒᵤₜ₊ and the falling edge slew rate of Vₒᵤₜ₋, thereby improving the rising edge slew rate of the differential output voltage.

When the input differential signal Vᵢₙ₋ -Vᵢₙ₊ >V_{P}, the principle is similar to the above, the output V_{A} of the first detection circuit 421 is at a low level, the output V_{B} of the second detection circuit 422 is at a high level, the first bias circuit 411 is turned off, the second bias circuit 412 provides current, the first control circuit 431 forms a source current to the output voltage end Vₒᵤₜ₊, and the second control circuit 432 forms a sink current to the output voltage end Vₒᵤₜ₋. Therefore, when the input differential signal Vᵢₙ₋−Vᵢₙ₊>V_{P}, the low-power self-biased slew rate enhancement circuit of the present application works, directly providing the output node of the operational amplifier with an additional source current to the output voltage end Vₒᵤₜ₊ and a sink current to the output voltage end Vₒᵤₜ₋, improving the falling edge slew rate of Vₒᵤₜ₊ and the rising edge slew rate of Vₒᵤₜ₋, thereby improving the falling edge slew rate of the differential output voltage.

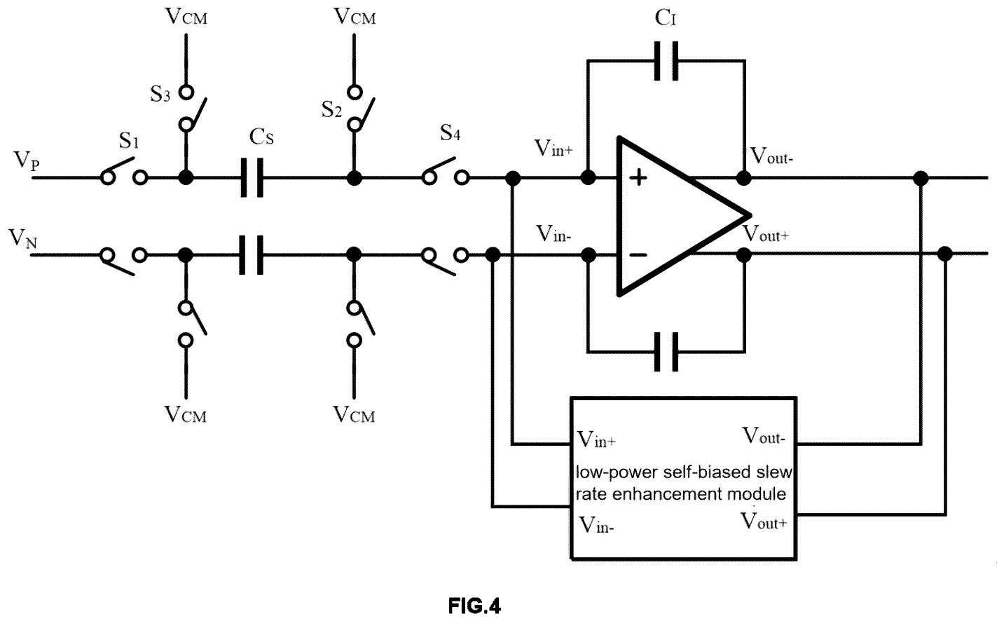

FIG. 4 is an application example of the self-biased slew rate enhancement circuit of the present application in a Sigma-Delta switched capacitor integrator, which is a switched capacitor integrator, with input signals V_{P} and VN, and output signals Vₒᵤₜ₊ and Vₒᵤₜ₋, including: an operational amplifier, a switched capacitor, and a self-biased slew rate enhancement circuit. The switched capacitor is differential, and its single end includes a first switch S1 to a fourth switch S4, a sampling capacitor Cs, and an integrating capacitor CI. The first switch S1 and the second switch S2 are controlled by a sampling phase timing ϕ1, and the third switch S3 and the fourth switch S4 are controlled by an integrating phase timing ϕ2. The two ends of the first switch S1 are respectively connected to the integrator positive input signal V_{P} and the lower plate of the sampling capacitor Cs, the two ends of the second switch S2 are respectively connected to the upper plate of Cs and the common mode voltage V_{CM}, the two ends of the third switch S3 are respectively connected to the lower plate of sampling capacitor Cs and the common mode voltage V_{CM}, the two ends of the fourth switch S4 are respectively connected to the upper plate of sampling capacitor Cs and the operational amplifier input end Vᵢₙ₊, and the integrating capacitor CI is connected across the input end Vᵢₙ₊ and the output end Vₒᵤₜ₋ of the operational amplifier. The low-power self-biased slew rate enhancement circuit is differential, and its input ends Vᵢₙ₊ and Vᵢₙ₋ are respectively connected to the input ends Vᵢₙ₊ and Vᵢₙ₋ of the operational amplifier, and its output ends Vₒᵤₜ₊ and Vₒᵤₜ₋ are respectively connected to the output ends Vₒᵤₜ₋ and Vₒᵤₜ₊ Of the operational amplifier. When the input differential voltage Vᵢₙ₊−Vᵢₙ₋ of the operational amplifier is less than the turn-on voltage V_{P}, the slew rate enhancement circuit does not work and does not consume current; when the input differential voltage Vᵢₙ₊−Vᵢₙ₋ of the operational amplifier is greater than the turn-on voltage V_{P}, the additional source current to output voltage end Vₒᵤₜ₊ and sink current to Vₒᵤₜ₋ are directly provided to the output node of the operational amplifier, thereby improving the falling edge slew rate of the differential output voltage; when the input differential voltage Vᵢₙ₋ -Vᵢₙ₊ of the operational amplifier is greater than the turn-on voltage V_{P}, the additional source current to output voltage end Vₒᵤₜ₊ and sink current to Vₒᵤₜ₋ are directly provided to the output node of the operational amplifier, thereby improving the rising edge slew rate of the differential output voltage. The self-biased slew rate enhancement circuit realizes rapid charge transfer between Cs and CI, and can increase the slew rate by 4 times or more, meeting the requirements of low-power consumption and high speed of the Sigma-Delta integrator.

In summary, the present application does not require additional bias voltage or bias current input, does not consume static current when the slew rate enhancement circuit function is not turned on, and does not need to increase the static bias current of the operational amplifier when the slew rate enhancement circuit is turned on. It can achieve fast charging and discharging of large capacitive loads without affecting the small signal frequency domain characteristics of the operational amplifier, enhance the bidirectional slew rate of the operational amplifier, and meet the low-power consumption and high-speed design requirements of the integrated circuit.

It should be noted that, in the embodiment of the present application, the low-power self-biased slew rate enhancement circuit can be used in other circuits in addition to being used in an integrator. The above embodiment only describes the integrator circuit.

The above embodiments are only used to illustrate the principle and effect of the present application, and are not used to limit the present application. Anyone familiar with this technology can modify or change the above embodiments as long as they are covered by the claims of the present application.

What is claimed is:

1. A low-power self-biased slew rate enhancement circuit, comprising:
differential input voltage positive and negative ends (Vᵢₙ₊, Vᵢₙ₋), differential output voltage positive and negative ends (Vₒᵤₜ₊, Vₒᵤₜ)₋, a self-bias control circuit, an input voltage detection circuit, and a slew rate control circuit, wherein
the differential input voltage positive and negative ends (Vᵢₙ₊, Vᵢₙ₋) are configured to connect to differential input voltage ends of an operational amplifier, and the differential output voltage positive and negative ends (Vₒᵤₜ₊, Vₒᵤₜ₋) are configured to connect to the differential output voltage ends of the operational amplifier;
the self-bias control circuit has an input end connected to an output end of an input voltage detection circuit and outputs a bias voltage based on an output voltage of the input voltage detection circuit;
the input voltage detection circuit has input ends connected to an output end and differential input voltage ends of the self-bias control circuit respectively; output ends of the input voltage detection circuit are connected to the input end of the self-bias control circuit and an input end of the slew rate control circuit respectively; and
the slew rate control circuit is connected to the differential output voltage positive and negative ends (Vₒᵤₜ₊, Vₒᵤₜ₋), and configured to:
provide a source current or a sink current to an output end of the operational amplifier when an output voltage of the differential input voltage positive and negative ends (Vᵢₙ₊, Vᵢₙ₋) exceeds a turn-on voltage so as to enhance a rising edge slew rate or a falling edge slew rate, and
generate no additional current and no slew rate enhancement effect when the output voltage of the differential input voltage positive and negative ends (Vᵢₙ₊, Vᵢₙ₋) does not exceed the turn-on voltage.

2. The low-power self-biased slew rate enhancement circuit according to claim 1, wherein
the self-bias control circuit includes a first bias circuit and a second bias circuit, and the input voltage detection circuit includes a first detection circuit and a second detection circuit;
the first bias circuit is configured to receive an output of the first detection circuit and generate a first bias voltage, which is connected to the first detection circuit to provide a bias current for the first detection circuit;
the second bias circuit is configured to receive an output of the second detection circuit and generate a second bias voltage, which is connected to the second detection circuit to provide a bias current for the second detection circuit;
the first detection circuit includes a first input end and a second input end, which are respectively connected to the differential input voltage positive and negative ends (Vᵢₙ₊, Vᵢₙ₋); and
the second detection circuit includes a third input end and a fourth input end, which are respectively connected to the differential input voltage positive and negative ends (Vᵢₙ₋, Vᵢₙ₊).

3. The low-power self-biased slew rate enhancement circuit according to claim 2, wherein the slew rate control circuit includes a first control circuit and a second control circuit, a first input end of the first control circuit is connected to an output end of the first detection circuit, a second input end of the first control circuit is connected to an output end of the second detection circuit, a first input end of the second control circuit is connected to a first output end of the second detection circuit, and a second input end of the second control circuit is connected to a second output end of the first detection circuit.

4. The low-power self-biased slew rate enhancement circuit according to claim 3, wherein
the first bias circuit includes a first PMOS transistor (M7a) and a first NMOS transistor (M6a), a gate of the first PMOS transistor (M7a) is connected to the output end of the first detection circuit, a source of the first PMOS transistor (M7a) is connected to a power supply voltage, a drain of the first PMOS transistor (M7a) is connected to a drain of the first NMOS transistor (M6a), a source of the first NMOS transistor (M6a) is grounded, the first NMOS transistor (M6a) adopts a diode-connected form, and a gate of the first NMOS transistor (M6a) is connected to the first detection circuit to provide a bias current for the first detection circuit; and
the second bias circuit includes a second PMOS transistor (M7b) and a second NMOS transistor (M6b), a gate of the second PMOS transistor (M7b) is connected to the output end of the second detection circuit, a source of the second PMOS transistor (M7b) is connected to a power supply voltage, a drain of the second PMOS transistor (M7b) is connected to a drain of the second NMOS transistor (M6b), a source of the second NMOS transistor (M6b) is grounded, the second NMOS transistor (M6b) adopts a diode-connected form, and a gate of the second NMOS transistor (M6b) is connected to the second detection circuit to provide a bias current for the second detection circuit.

5. The low-power self-biased slew rate enhancement circuit according to claim 3, wherein
the first detection circuit includes a third NMOS transistor (M5a), a fourth NMOS transistor (M1a), a fifth NMOS transistor (M2a), a third PMOS transistor (M3a), and a fourth PMOS transistor (M4a); a gate of the third NMOS transistor (M5a) is connected to a gate of a first NMOS transistor, a source of the third NMOS transistor (M5a) is grounded, a drain of the third NMOS transistor (M5a) is respectively connected to a source of the fourth NMOS transistor and a source of the fifth NMOS transistor (M2a), a gate of the fourth NMOS transistor and a gate of the fifth NMOS transistor (M2a) are respectively connected to the differential input voltage positive and negative ends (Vᵢₙ₊, Vᵢₙ₋), a drain of the fourth NMOS transistor is connected to a drain of the third PMOS transistor (M3a), the third PMOS transistor (M3a) adopts a diode-connected form, a source of the third PMOS transistor (M3a) is connected to a power supply voltage, a drain of the fifth NMOS transistor (M2a) is connected to a drain of the fourth PMOS transistor (M4a) and forms the output end of the first detection circuit, a gate of the fourth PMOS transistor (M4a) is connected to a gate of the third NMOS transistor (M5a), and a source of the fourth PMOS transistor (M4a) is connected to the power supply voltage; and
the second detection circuit includes a sixth NMOS transistor (M5b), a seventh NMOS transistor (M1b), an eighth NMOS transistor (M2b), a fifth PMOS transistor (M3b), and a sixth PMOS transistor (M4b); a gate of the sixth NMOS transistor (M5b) is connected to a gate of the second NMOS transistor, a source of the sixth NMOS transistor (M5b) is grounded, a drain of the sixth NMOS transistor (M5b) is respectively connected to a source of the seventh NMOS transistor (M1b) and a source of the eighth NMOS transistor (M2b), a gate of the seventh NMOS transistor (M1b) and a gate of the eighth NMOS transistor (M2b) are respectively connected to the differential input voltage positive and negative ends (Vᵢₙ₊, Vᵢₙ₋), a drain of the seventh NMOS transistor (M1b) is connected to a drain of the fifth PMOS transistor (M3b), the fifth PMOS transistor (M3b) adopts a diode-connected form, a source of the fifth PMOS transistor (M3b) is connected to the power supply voltage, a drain of the eighth NMOS transistor (M2b) is connected to a drain of the sixth PMOS transistor (M4b) and forms the second output end of the second detection circuit, a gate of the fifth PMOS transistor (M3b) is connected to a gate of the sixth PMOS transistor (M4b), and a source of the sixth PMOS transistor (M4b) is connected to the power supply voltage.

6. The low-power self-biased slew rate enhancement circuit according to claim 3, wherein
the first control circuit includes a ninth NMOS transistor (M1n), a tenth NMOS transistor (M4n), a seventh PMOS transistor (M1p), and an eighth PMOS transistor (M4p), a source of the seventh PMOS transistor (M1p) is connected to a power supply voltage, a gate of the seventh PMOS transistor (M1p) is connected to the output end of the first detection circuit, a drain of the seventh PMOS transistor (M1p) is connected to a drain of the ninth NMOS transistor (M1n), a source of the ninth NMOS transistor (M1n) is grounded, the ninth NMOS transistor (M1n) adopts a diode-connected form, a source of the eighth PMOS transistor (M4p) is connected to the power supply voltage, a gate of the eighth PMOS transistor (M4p) is connected to the output end of the second detection circuit, a drain of the eighth PMOS transistor (M4p) is connected to a drain of the tenth NMOS transistor (M4n) and connected to the differential output voltage positive end (Vₒᵤₜ₊), a source of the tenth NMOS transistor (M4n) is grounded, and a gate of the tenth NMOS transistor (M4n) is connected to a drain of the ninth NMOS transistor (M1n); and
the second control circuit includes an eleventh NMOS transistor (M2n), a twelfth NMOS transistor (M3n), a ninth PMOS transistor (M2p), and a tenth PMOS transistor (M3p), a source of the ninth PMOS transistor (M2p) is connected to the power supply voltage, a gate of the ninth PMOS transistor (M2p) is connected to the output end of the second detection circuit, a drain of the ninth NMOS transistor (M1n) is connected to a drain of the eleventh NMOS transistor (M2n), a source of the eleventh NMOS transistor (M2n) is grounded, the eleventh NMOS transistor (M2n) adopts a diode-connected form, a source of the tenth PMOS transistor (M3p) is connected to the power supply voltage, a gate of the tenth PMOS transistor (M3p) is connected to the output end of the first detection circuit, a drain of the tenth PMOS transistor (M3p) is connected to a drain of the twelfth NMOS transistor (M3n) and connected to the differential output voltage negative end (Vₒᵤₜ₋), a source of the twelfth NMOS transistor (M3n) is grounded, and a gate of the twelfth NMOS transistor (M3n) is connected to a drain of the eleventh NMOS transistor (M2n).

7. The low-power self-biased slew rate enhancement circuit according to claim 3, wherein
the first bias circuit includes a first PMOS transistor (M6a) and a first NMOS transistor (M7a), the first PMOS transistor (M6a) adopts a diode-connected form, a source of the first PMOS transistor (M6a) is connected to a power supply voltage, a drain of the first PMOS transistor is connected to a drain of the first NMOS transistor (M7a), a source of the first NMOS transistor (M7a) is grounded, a gate of the first NMOS transistor (M7a) is connected to the output end of the first detection circuit, and a gate of the first PMOS transistor (M6a) is connected to the first detection circuit to provide a bias current for the first detection circuit; and
the second bias circuit includes a second PMOS transistor (M6b) and a second NMOS transistor (M7b), the second PMOS transistor (M6b) adopts a diode-connected form, and a source of the second PMOS transistor (M6b) is connected to the power supply voltage, a drain of the second PMOS transistor is connected to a drain of the second NMOS transistor (M7b), a source of the second NMOS transistor (M7b) is grounded, a gate of the second NMOS transistor (M7b) is connected to the output end of the first detection circuit, and a gate of the second PMOS transistor is connected to the first detection circuit to provide a bias current for the first detection circuit.

8. The low-power self-biased slew rate enhancement circuit according to claim 7, wherein
the first detection circuit includes: a third NMOS transistor (M3a), a fourth NMOS transistor (M4a), a third PMOS transistor (M5a), a fourth PMOS transistor (M1a), and a fifth PMOS transistor (M2a); a source of the third PMOS transistor (M5a) is connected to the power supply voltage, a gate of the third PMOS transistor (M5a) is connected to the gate of the first PMOS transistor (M6a), a drain of the third PMOS transistor (M5a) is respectively connected to a source of the fourth PMOS transistor (M1a) and a source of the fifth PMOS transistor (M2a), and a gate of the fourth PMOS transistor (M1a) and a gate of the fifth PMOS transistor (M2a) are respectively connected to the differential input voltage positive and negative ends (Vᵢₙ₊, Vᵢₙ₋), a drain of the fourth PMOS transistor (M1a) is connected to a drain of the third NMOS transistor (M3a), a source of the third NMOS transistor (M3a) is grounded, the third NMOS transistor (M3a) adopts a diode-connected form, a drain of the fifth PMOS transistor (M2a) is connected to a drain of the fourth NMOS transistor (M4a), a gate of the fourth NMOS transistor (M4a) is connected to a gate of the third NMOS transistor (M3a), and a source of the fourth NMOS transistor (M4a) is grounded; and
the second detection circuit includes: a fifth NMOS transistor (M3b), a sixth NMOS transistor (M4b), a sixth PMOS transistor (M5b), a seventh PMOS transistor (M1b), and an eighth PMOS transistor (M2b); a source of the sixth PMOS transistor (M5b) is connected to the power supply voltage, a gate of the sixth PMOS transistor (M5b) is connected to the gate of the second PMOS transistor (M6b), a drain of the sixth PMOS transistor (M5b) is respectively connected to a source of the seventh PMOS transistor (M1b) and a source of the eighth PMOS transistor (M2b), a gate of the seventh PMOS transistor (M1b) and a gate of the eighth PMOS transistor (M2b) are respectively connected to the differential input voltage positive and negative ends (Vᵢₙ₊, Vᵢₙ₋), a drain of the seventh PMOS transistor (M1b) is connected to a drain of the fifth NMOS transistor (M3b), a source of the fifth NMOS transistor (M3b) is grounded, the fifth NMOS transistor (M3b) adopts a diode-connected form, a drain of the eighth PMOS transistor (M2b) is connected to a drain of the sixth NMOS transistor (M4b), a gate of the sixth NMOS transistor (M4b) is connected to a gate of the fifth NMOS transistor (M3b), and a source of the sixth NMOS transistor (M4b) is grounded.

9. The low-power self-biased slew rate enhancement circuit according to claim 8, wherein
the first control circuit includes a ninth PMOS transistor (M1p), a tenth PMOS transistor (M4p), a seventh NMOS transistor (M1n), and an eighth NMOS transistor (M4n), the ninth PMOS transistor (M1p) adopts a diode-connected form, a source of the ninth PMOS transistor (M1p) is connected to the power supply voltage, a drain of the ninth PMOS transistor (M1p) is connected to a drain of the seventh NMOS transistor (M1n), a source of the seventh NMOS transistor (M1n) is grounded, a gate of the seventh NMOS transistor (M1n) is connected to the output end of the first detection circuit, a source of the tenth PMOS transistor (M4p) is connected to the power supply voltage, a gate of the tenth PMOS transistor (M4p) is connected to a drain of the ninth PMOS transistor (M1p), a drain of the tenth PMOS transistor (M4p) is connected to a drain of the eighth NMOS transistor (M4n) and is connected to the differential output voltage positive end (Vₒᵤₜ₊), a gate of the eighth NMOS transistor (M4n) is connected to the output end of the second detection circuit, and a source of the eighth NMOS transistor (M4n) is grounded; and
the first control circuit includes an eleventh PMOS transistor (M2p), a twelfth PMOS transistor (M3p), a ninth NMOS transistor (M2n), and a tenth NMOS transistor (M3n), the eleventh PMOS transistor (M2p) adopts a diode-connected form, a source of the eleventh PMOS transistor (M2p) is connected to the power supply voltage, a drain of the eleventh PMOS transistor (M2p) is connected to a drain of the seventh NMOS transistor (M2n), a source of the ninth NMOS transistor (M2n) is grounded, a gate of the ninth NMOS transistor (M2n) is connected to the second output end of the first detection circuit, a source of the twelfth PMOS transistor (M3p) is connected to the power supply voltage, a gate of the twelfth PMOS transistor (M3p) is connected to a drain of the eleventh PMOS transistor (M2p), a drain of the twelfth PMOS transistor (M3p) is connected to a drain of the tenth NMOS transistor (M3n) and to the differential output voltage negative end (Vₒᵤₜ₋), a gate of the tenth NMOS transistor (M3n) is connected to the first output end of the second detection circuit, and a source of the tenth NMOS transistor (M3n) is grounded.

10. An integrator, comprising:
a low-power self-biased slew rate enhancement circuit;
an operational amplifier; and
a switch capacitor,
wherein
the low-power self-biased slew rate enhancement circuit includes: differential input voltage positive and negative ends (Vᵢₙ₊, Vᵢₙ₋), differential output voltage positive and negative ends (Vₒᵤₜ₊, Vₒᵤₜ₋), a self-bias control circuit, an input voltage detection circuit, and a slew rate control circuit, wherein
the differential input voltage positive and negative ends (Vᵢₙ₊, Vᵢₙ₋) are configured to connect to differential input voltage ends of an operational amplifier, and the differential output voltage positive and negative ends (Vₒᵤₜ₊, Vₒᵤₜ₋) are configured to connect to the differential output voltage ends of the operational amplifier;
the self-bias control circuit has an input end connected to an output end of an input voltage detection circuit and outputs a bias voltage based on an output voltage of the input voltage detection circuit;
the input voltage detection circuit has input ends connected to an output end and differential input voltage ends of the self-bias control circuit respectively; output ends of the input voltage detection circuit are connected to the input end of the self-bias control circuit and an input end of the slew rate control circuit respectively; and
the slew rate control circuit is connected to the differential output voltage positive and negative ends (Vₒᵤₜ₊, Vₒᵤₜ₋), and configured to:
provide a source current or a sink current to an output end of the operational amplifier when an output voltage of the differential input voltage positive and negative ends (Vᵢₙ₊, Vᵢₙ₋) exceeds a turn-on voltage so as to enhance a rising edge slew rate or a falling edge slew rate, and
generate no additional current and no slew rate enhancement effect when the output voltage of the differential input voltage positive and negative ends (Vᵢₙ₊, Vᵢₙ₋) does not exceeds the turn-on voltage,
the switch capacitor is differential, and a single-end of the switch capacitor includes a first switch (S1), a second switch (S2), a third switch (S3), a fourth switch (S4), a sampling capacitor (Cs), and an integration capacitor (C1),
the first switch (S1) and the second switch (S2) are controlled by a sampling phase timing (ϕ1), and the third switch (S3) and the fourth switch (S4) are controlled by an integrating phase timing (ϕ2), a first end of the first switch (S1) is connected to an input voltage (V_{P}) of an integrator, and a second end of the first switch (S1) is connected to a lower plate of the sampling capacitor (Cs), two ends of the second switch (S2) are respectively connected to an upper plate of the sampling capacitor (Cs) and a common mode voltage (V_{CM}), two ends of the third switch (S3) are respectively connected to the lower plate of the sampling capacitor (Cs) and the common mode voltage (V_{CM}), two ends of the fourth switch (S4) are respectively connected to the upper plate of the sampling capacitor (Cs) and an input positive end (Vᵢₙ₊) of the operational amplifier, and the integration capacitor (C1) is connected across the input positive end (Vᵢₙ₊) and the output negative end (Vₒᵤₜ₋) of the operational amplifier;
the low-power self-biased slew rate enhancement circuit is differential, and the differential input voltage positive and negative ends (Vᵢₙ₊, Vᵢₙ₋) of the low-power self-biased slew rate enhancement circuit are respectively connected to the differential input voltage positive and negative ends (Vᵢₙ₊, Vᵢₙ₋) of the operational amplifier, and the differential output voltage positive and negative ends (Vₒᵤₜ₊, Vₒᵤₜ₋) of the low-power self-biased slew rate enhancement circuit are respectively connected to the differential output voltage positive and negative ends (Vₒᵤₜ₋, Vₒᵤₜ₊) of the operational amplifier.
